(19) United States
(12) Patent Application Publication
(10) Pub. No.: US 2015/0041042 A1
(43) Pub. Date: Feb. 12, 2015

(54) PRESSURE SENSITIVE ADHESIVE TYPE OF WAVELENGTH CONVERSION TAPE FOR ENHANCING SOLAR HARVESTING EFFICIENCY

(71) Applicant: NITTO DENKO CORPORATION, Osaka (JP)

(72) Inventors: Hongxi Zhang, Temecula, CA (US); Michiharu Yamamoto, Carlsbad, CA (US)

(21) Appl. No.: 14/375,956

(22) PCT Filed: Jan. 31, 2013
(86) PCT No.: PCT/US13/24212

§ 371 Date: Jul. 31, 2014

Related U.S. Application Data
(60) Provisional application No. 61/593,720, filed on Feb. 1, 2012.
(60) Provisional application No. 61/594,288, filed on Feb. 2, 2012.

(51) Int. Cl. C09J 11/06; C09J 7/02; H01L 31/0232; B29C 65/50; H01L 31/18; C09J 7/00; C08K 5/3475

(52) U.S. Cl. CPC C09J 11/06; C09J 7/00; C09J 7/0246; C08K 5/3475; B29C 65/50; H01L 31/18; H01L 31/02327; C09J 133/08
USPC 156/60; 428/355 R; 428/220; 428/41.6; 428/40.9; 428/40.6; 428/41.3; 428/40.7; 428/40.8; 523/135

(57) ABSTRACT

Described herein are pressure sensitive adhesive type of wavelength conversion tapes that are easy-to-apply to a solar harvesting device using an adhesive layer. The pressure sensitive adhesive type of wavelength conversion tape comprises a pressure sensitive adhesive layer, wherein the pressure sensitive adhesive layer comprises one, or multiple, luminescent dyes that convert photons of a particular wavelength to a different more desirable wavelength. The adhesive layer is designed to adhere to the light incident surface of a solar harvesting device such as a solar cell, solar panel, or photovoltaic device, to improve the efficiency of the device.

### CROSS-REFERENCE TO RELATED APPLICATIONS

This patent application claims the benefit of priority to U.S. Provisional Patent Application No. 61/593,720, filed Feb. 1, 2012 and U.S. Provisional Patent Application No. 61/594,288, filed Feb. 2, 2012. All of the foregoing applications are fully incorporated by reference for all purposes.

### BACKGROUND OF THE INVENTION

1. Field of the Invention

The present invention generally relates to a pressure sensitive adhesive type of wavelength conversion tape, which is easy-to-apply to solar cells, solar panels, or photovoltaic devices, and is useful for improving the solar harvesting efficiency of these devices.

2. Description of the Related Art

The utilization of solar energy offers a promising alternative energy source to the traditional fossil fuels, and therefore, the development of devices that can convert solar energy into electricity, such as photovoltaic devices (also known as solar cells), has drawn significant attention in recent years. Several different types of mature photovoltaic devices have been developed, including a Silicon based device, a III-V and II-VI PN junction device, a Copper-Indium-Gallium-Selenium (CIGS) thin film device, an organic sensitizer device, an organic thin film device, and a Cadmium Sulfide/Cadmium Telluride (CdS/CdTe) thin film device, to name a few. More detail on these devices can be found in the literature, such as Lin et al., “High Photoelectric Conversion Efficiency of Metal Phthalocyanine/Fullerene Heterojunction Photovoltaic Device” (International Journal of Molecular Sciences 2011). However, the photoelectric conversion efficiency of many of these devices still has room for improvement and development of techniques to improve this efficiency has been an ongoing challenge for many researchers.

Recently, one technique developed to improve the efficiency of photovoltaic devices is to utilize a wavelength down-shifting film. Many of the photovoltaic devices are unable to effectively utilize the entire spectrum of light as the materials on the device absorb certain wavelengths of light (typically the shorter UV wavelengths) instead of allowing the light to pass through to the photoconductive material layer where it can be converted into electricity. Application of a wavelength down-shifting film absorbs the shorter wavelength photons and re-emits them at more favorable longer wavelengths, which can then be absorbed by the photoconductive layer in the device, and converted into electricity.

This phenomenon is often observed in the thin film CdS/CdTe and CIGS solar cells which both use CdS as the window layer. The low cost and high efficiency of these thin film solar cells has drawn significant attention in recent years, with typical commercial cells having photoelectric conversion efficiencies of 10-16%. However, one issue with these devices is the energy gap of CdS, approximately 2.41 eV, which causes light at wavelengths below 514 nm to be absorbed by CdS instead of passing through to the photoconductive layer where it can be converted into energy. This inability to utilize the entire spectrum of light effectively reduces the overall photoelectric conversion efficiency of the device.

There have been numerous reports disclosing the utilization of a wavelength down-shifting material to improve the performance of photovoltaic devices. For example, U.S. Patent Application Publication No. 2009/0151785 discloses a silicon based solar cell which contains a wavelength down-shifting inorganic phosphor material. U.S. Patent Application Publication No. US 2011/0011455 discloses an integrated solar cell comprising a plasmonic layer, a wavelength conversion layer, and a photovoltaic layer. U.S. Pat. No. 7,791,157 discloses a solar cell with a wavelength conversion layer containing a quantum dot compound. U.S. Patent Application Publication No. 2010/0294339 discloses an integrated photovoltaic device containing a luminescent down-shifting material, however no example embodiments were constructed. U.S. Patent Application Publication No. 2010/0012183 discloses a thin film solar cell with a wavelength down-shifting photo-luminescent medium; however, no examples are provided. U.S. Patent Application Publication No. 2008/0236667 discloses an enhanced spectrum conversion film made in the form of a thin film polymer comprising an inorganic fluorescent powder. However, each of these patents and patent application publications, which are incorporated herein by reference in their entirety, use time consuming and sometimes complicated and expensive techniques which may require special tool sets to apply the wavelength conversion film to the solar cell device. These techniques include spin coating, drop casting, sedimentation, solvent evaporation, chemical vapor deposition, physical vapor deposition, etc.

### SUMMARY OF THE INVENTION

A pressure sensitive adhesive type of wavelength conversion tape that includes a pressure sensitive adhesive layer is provided. In several embodiments, such wavelength conversion tapes are configured to be easy-to-apply to solar harvesting devices, such as solar cells, solar panels, and photovoltaic devices. Several embodiments provide devices that can enhance solar harvesting efficiency when applied to the light incident surface of those devices. In several embodiments, the pressure sensitive adhesive tape for wavelength conversion comprises a pressure sensitive adhesive layer. In several embodiments, the pressure sensitive adhesive layer comprises an adhesive polymeric material and at least one luminescent dye. In some embodiments the tape receives, as input, at least one photon having a first wavelength, and provides, as output, at least one photon having a second wavelength which is different than the first. In some embodiments, the pressure sensitive adhesive layer is optically transparent.

The pressure sensitive adhesive type of wavelength conversion tapes described herein may include additional layers. For example, the tape may comprise a removable liner adjacent to the adhesive layer. In some embodiments the tape is applied to the solar cell, solar panel, or photovoltaic device, by removing the removable liner (if present) and pressing the exposed pressure sensitive adhesive layer surface onto the light incident surface of the solar cell, solar panel, or photovoltaic device. In some embodiments the application of the tape to a solar cell, solar panel, or photovoltaic device improves the solar harvesting efficiency of the device.

In some embodiments, the pressure sensitive adhesive tape may further comprise a substrate layer. The substrate layer comprises a polymer material. In some embodiments, the substrate layer is optically transparent. Another aspect of the invention relates to a method for improving the performance of photovoltaic devices, solar cells, solar modules, or solar panels, comprising applying the pressure sensitive adhesive type of wavelength conversion tape, as described herein, and adhering the adhesive layer to the light incident side of the device. The solar harvesting efficiency of various devices, such as a silicon based device, a III-V or II-VI junction device, a Copper-Indium-Gallium-Selenium (CIGS) thin film device, an organic sensitizer device, an organic thin film device, or a Cadmium Sulfide/Cadmium Telluride (CdS/CdTe) thin film device, can be improved.

The pressure sensitive adhesive type of wavelength conversion tape may be provided in the form of a roll, having various lengths and widths so as to accommodate smaller individual solar cells, or entire solar panels. A roll laminator may be used to apply the tape to the device. The tape may be applied to rigid devices or it may be applied to flexible devices. The tape may be cut to any desired size using standard methods of cutting.

For purposes of summarizing aspects of the invention and the advantages achieved over the related art, certain objects and advantages of the invention are described in this disclosure. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught herein without necessarily achieving other objects or advantages as may be taught or suggested herein.

These and other embodiments are described in greater detail below.

### BRIEF DESCRIPTION OF THE DRAWINGS

FIG. 1 illustrates one embodiment of pressure sensitive adhesive type of wavelength conversion tape.

FIG. 2 illustrates another embodiment of pressure sensitive adhesive type of wavelength conversion tape.

FIG. 3 illustrates one embodiment of pressure sensitive adhesive type of wavelength conversion tape.

FIG. 4 shows the absorption (solid line) and emission spectra (dashed line) of the Example 1 (BA/AA) and Comparative Example 2 (EVA) samples.

### DETAILED DESCRIPTION OF THE PREFERRED EMBODIMENT

The present disclosure relates to a pressure sensitive adhesive type of wavelength conversion tape. When the tape is applied to the light incident surface of a solar harvesting device, such as a solar cell, solar panel, or photovoltaic device, the photoelectric conversion efficiency is enhanced. The inventors recently discovered that a pressure sensitive adhesive type of wavelength conversion tape can be constructed comprising a pressure sensitive adhesive layer, which can be easily applied to a solar harvesting device by pressing the adhesive layer onto the light incident surface of the solar harvesting device. Application of the pressure sensitive adhesive type of wavelength conversion tape enhances the solar harvesting efficiency of the solar cell device. The pressure sensitive adhesive type of wavelength conversion tape can be constructed to be compatible with all different types of solar cells and solar panels, including Silicon based devices, III-V and II-VI PN junction devices, CIGS thin film devices, organic sensitizer devices, organic thin film devices, CdS/CdTe thin film devices, dye sensitized devices, etc. Devices, such as an amorphous Silicon solar cell, a microcrystalline Silicon solar cell, and a crystalline Silicon solar cell, can also be improved. Additionally, the tape is applicable to new devices or older, already in service devices, and can be cut as needed to fit the device.

A chromophore compound, sometimes referred to as a luminescent dye or florescent dye, is a compound that absorbs photons of a particular wavelength or wavelength range, and re-emits the photon at a different wavelength or wavelength range. Chromophores used in film media can greatly enhance the performance of solar harvesting devices. Since such devices are often exposed to extreme environmental conditions for a long period of time, e.g., 20 plus years, maintaining the stability of the chromophore is important. In some embodiments, chromophore compounds with good photostability for long periods of time, e.g., 20,000 plus hours of illumination under one sun (AM1.5 G) irradiation with <10% degradation, are preferably used in the pressure sensitive adhesive type of wavelength conversion tape described herein.

In some embodiments, the chromophore is configured to convert incoming photons of a first wavelength to a different second wavelength. Various chromophores can be used. In some embodiments, the at least one chromophore is an organic dye. In some embodiments, the at least one chromophore is selected from perylene derivative dyes, benzotriazole derivative dyes, benzothiadiazole derivative dyes, and combinations thereof.

In some embodiments, the chromophores represented by general formulae I-a, I-b, II-a, II-b, III-a, III-b, IV and V are useful as fluorescent dyes in various applications, including in wavelength conversion films. As shown in the formulae, the dye comprises a benzo heterocyclic system in some embodiments. In some embodiments, perylene derivative dye may be used. Additional detail and examples, without limiting the scope of the invention, on the types of compounds that can be used are described below.

As used herein, an “electron donor group” is defined as any group which increases the electron density of the 2H-benzo[d][1,2,3]triazole system.

An “electron donor linker” is defined as any group that can link two 2H-benzo[d][1,2,3]triazole systems providing conjugation of their π orbitals, which can also increase or have neutral effect on the electron density of the 2H-benzo[d][1,2,3]triazole to which they are connected.

An “electron acceptor group” is defined as any group which decreases the electron density of the 2H-benzo[d][1,2,3]triazole system. The placement of an electron acceptor group at the N-2 position of the 2H-benzo[d][1,2,3]triazole ring system.

The term “alkyl” refers to a branched or straight fully saturated acyclic aliphatic hydrocarbon group (i.e. composed of carbon and hydrogen containing no double or triple bonds). Alkyls include, but are not limited to, methyl, ethyl, propyl, isopropyl, butyl, isobutyl, tertiary butyl, pentyl, hexyl, and the like.

The term “heteroalkyl” used herein refers to an alkyl group comprising one or more heteroatoms. When two or more heteroatoms are present, they may be the same or different.

The term “cycloalkyl” used herein refers to saturated aliphatic ring system radical having three to twenty carbon atoms including, but not limited to, cyclopropyl, cyclopentyl, cyclohexyl, cycloheptyl, and the like.

The term “alkenyl” used herein refers to a monovalent straight or branched chain radical of from two to twenty carbon atoms containing a carbon double bond including, but not limited to, 1-propenyl, 2-propenyl, 2-methyl-1-propenyl, 1-butenyl, 2-butenyl, and the like.

The term “alkynyl” used herein refers to a monovalent straight or branched chain radical of from two to twenty carbon atoms containing a carbon triple bond including, but not limited to, 1-propynyl, 1-butynyl, 2-butynyl, and the like.

The term “aryl” used herein refers to homocyclic aromatic radical whether one ring or multiple fused rings. Examples of aryl groups include, but are not limited to, phenyl, naphthyl, phenanthrenyl, naphthacenyl, fluorenyl, pyrenyl, and the like. Further examples include:

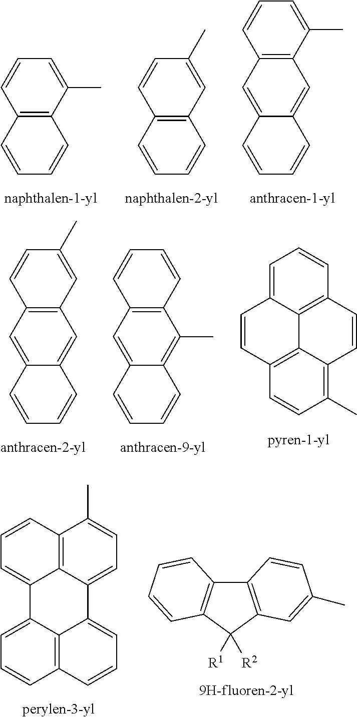

The term “heteroaryl” used herein refers to an aromatic group comprising one or more heteroatoms, whether one ring or multiple fused rings. When two or more heteroatoms are present, they may be the same or different. In fused ring systems, the one or more heteroatoms may be present in only one of the rings. Examples of heteroaryl groups include, but are not limited to, benzothiazyl, benzoxazyl, quinazolinyl, quinolinyl, isoquinolinyl, quinoxalinyl, pyridinyl, pyrrolyl, oxazolyl, indolyl, thiazyl and the like.

The term “alkaryl” or “alkylaryl” used herein refers to an alkyl-substituted aryl radical. Examples of alkaryl include, but are not limited to, ethylphenyl, 9,9-dihexyl-9H-fluorene, and the like.

The term “aralkyl” or “arylalkyl” used herein refers to an aryl-substituted alkyl radical. Examples of aralkyl include, but are not limited to, phenylpropyl, phenylethyl, and the like.

The term “heteroaryl” used herein refers to an aromatic ring system radical in which one or more ring atoms are heteroatoms, whether one ring or multiple fused rings. When two or more heteroatoms are present, they may be the same or different. In fused ring systems, the one or more heteroatoms may be present in only one of the rings. Examples of heteroaryl groups include, but are not limited to, benzothiazyl, benzoxazyl, quinazolinyl, quinolinyl, isoquinolinyl, quinoxalinyl, pyridinyl, pyridazinyl, pyrimidinyl, pyrazinyl, pyrrolyl, oxazolyl, indolyl, and the like. Further examples of substituted and unsubstituted heteroaryl rings include:

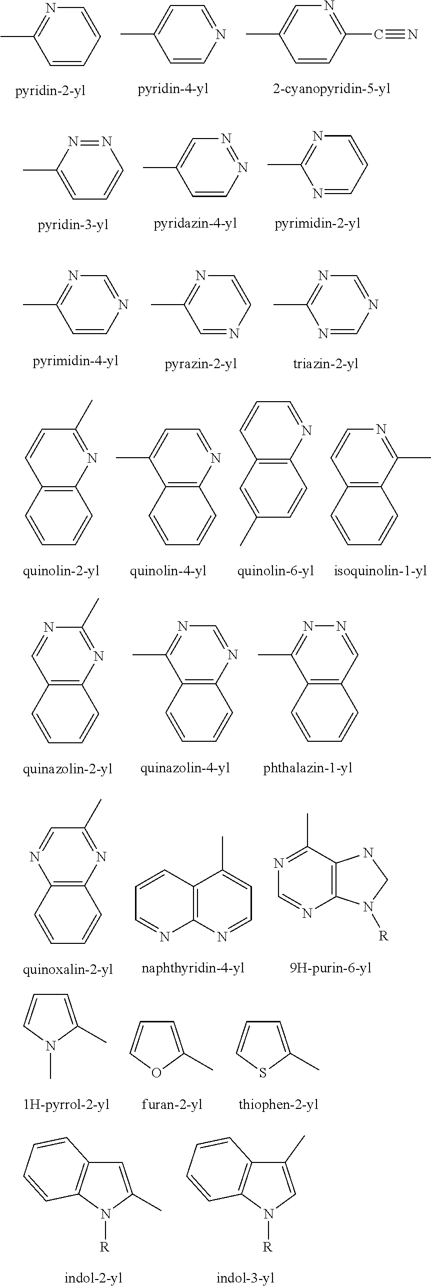

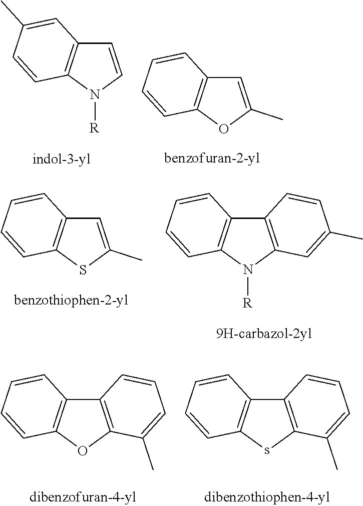

The term “alkoxy” used herein refers to straight or branched chain alkyl radical covalently bonded to the parent molecule through an —O— linkage. Examples of alkoxy groups include, but are not limited to, methoxy, ethoxy, propoxy, isopropoxy, butoxy, n-butoxy, sec-butoxy, t-butoxy and the like.

The term “heteroatom” used herein refers to S (sulfur), N (nitrogen), and O (oxygen).

The term “cyclic amino” used herein refers to either secondary or tertiary amines in a cyclic moiety. Examples of cyclic amino groups include, but are not limited to, aziridinyl, piperidinyl, N-methylpiperidinyl, and the like.

The term “cyclic imido” used herein refers to an imide in the radical of which the two carbonyl carbons are connected by a carbon chain. Examples of cyclic imide groups include, but are not limited to, 1,8-naphthalimide, pyrrolidine-2,5-dione, 1H-pyrrole-2,5-dione, and the likes.

The term “aryloxy” used herein refers to an aryl radical covalently bonded to the parent molecule through an —O— linkage.

The term “acyloxy” used herein refers to a radical R—C(═O)O—.

The term “carbamoyl” used herein refers to —NHC(═O)R.

The term “keto” and “carbonyl” used herein refers to C═O.

The term “carboxy” used herein refers to —COOR.

The term “ester” used herein refers to —C(═O)O—.

The term “amido” used herein refers to —NRC(═O)R′.

The term “amino” used herein refers to —NR′R″

As used herein, a substituted group is derived from the unsubstituted parent structure in which there has been an exchange of one or more hydrogen atoms for another atom or group. When substituted, the substituent group(s) is (are) one or more group(s) individually and independently selected from C₁-C₆ alkyl, C₁-C₆ alkenyl, C₁-C₆ alkynyl, C₃-C₇ cycloalkyl (optionally substituted with halo, alkyl, alkoxy, carboxyl, haloalkyl, CN, —SO₂-alkyl, —CF₃, and —OCF₃), cycloalkyl geminally attached, C₁-C₆ heteroalkyl, C₃-C₁₀ heterocycloalkyl (e.g., tetrahydrofuryl) (optionally substituted with halo, alkyl, alkoxy, carboxyl, CN, —SO₂-alkyl, —CF₃, and —OCF₃), aryl (optionally substituted with halo, alkyl, aryl optionally substituted with C₁-C₆ alkyl, arylalkyl, alkoxy, aryloxy, carboxyl, amino, imido, amido (carbamoyl), optionally substituted cyclic imido, cylic amido, CN, —NH—C(═O)-alkyl, —CF₃, and —OCF₃), arylalkyl (optionally substituted with halo, alkyl, alkoxy, aryl, carboxyl, CN, —SO₂-alkyl, —CF₃, and —OCF₃), heteroaryl (optionally substituted with halo, alkyl, alkoxy, aryl, heteroaryl, aralkyl, carboxyl, CN, —SO₂-alkyl, —CF₃, and —OCF₃), halo (e.g., chloro, bromo, iodo and fluoro), cyano, hydroxy, optionally substituted cyclic imido, amino, imido, amido, —CF₃, C₁-C₆ alkoxy, aryloxy, acyloxy, sulfhydryl (mercapto), halo(C₁-C₆)alkyl, C₁-C₆ alkylthio, arylthio, mono- and di-(C₁-C₆)alkyl amino, quaternary ammonium salts, amino(C₁-C₆)alkoxy, hydroxy(C₁-C₆)alkylamino, amino(C₁-C₆)alkylthio, cyanoamino, nitro, carbamoyl, keto (oxy), carbonyl, carboxy, glycolyl, glycyl, hydrazino, guanyl, sulfamyl, sulfonyl, sulfinyl, thiocarbonyl, thiocarboxy, sulfonamide, ester, C-amide, N-amide, N-carbamate, O-carbamate, urea and combinations thereof. Wherever a substituent is described as “optionally substituted” that substituent can be substituted with the above substituents.

### Formulae I-a and I-b

Some embodiments provide a chromophore having one of the structures below:

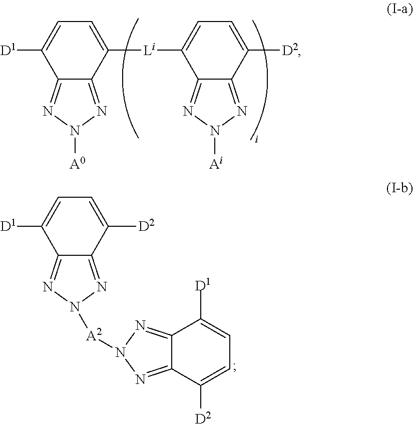

wherein D¹ and D² are electron donating groups, Lⁱ is an electron donor linker, and A⁰ and Aⁱ are electron acceptor groups. In some embodiments, where more than one electron donor group is present, the other electron donor groups may be occupied by another electron donor, a hydrogen atom, or another neutral substituent. In some embodiments, at least one of the D¹, D², and Lⁱ is a group which increases the electron density of the 2H-benzo[d][1,2,3]triazole system to which it is attached.

In formulae I-a and I-b, i is an integer in the range of 0 to 100. In some embodiments, i is an integer in the range of 0 to 50, 0 to 30, 0 to 10, 0 to 5, or 0 to 3. In some embodiments, i is 0, 1, 2, 3, 4, 5, 6, 7, 8, 9, or 10.

In formulae I-a and I-b, A⁰ and Aⁱ are each independently selected from the group consisting of optionally substituted alkyl, optionally substituted alkenyl, optionally substituted heteroalkyl, optionally substituted aryl, optionally substituted heteroaryl, optionally substituted amino, optionally substituted amido, optionally substituted cyclic amido, optionally substituted cyclic imido, optionally substituted alkoxy, and optionally substituted carboxy, and optionally substituted carbonyl.

In some embodiments, A⁰ and Aⁱ are each independently selected from the group consisting of optionally substituted heteroaryl, optionally substituted aryl, optionally substituted cyclic imido, optionally substituted C₁₋₈ alkyl, and optionally substituted C₁₋₈ alkenyl; wherein the substituent for optionally substituted heteroaryl is selected from the group consisting of alkyl, aryl and halogen; the substitutent for optionally substituted aryl is —NR′—C(═O)R² or optionally substituted cyclic imido, wherein R¹ and R² are as described above.

In some embodiments, A⁰ and A are each independently phenyl substituted with a moiety selected from the group consisting of —NR′—C(═O)R² and optionally substituted cyclic imido, wherein R¹ and R² are as described above.

In some embodiments, A⁰ and Aⁱ are each optionally substituted heteroaryl or optionally substituted cyclic imido; wherein the substituent for optionally substituted heteroaryl and optionally substituted cyclic imido is selected from the group consisting of alkyl, aryl and halogen. In some embodiments, at least one of the A⁰ and Aⁱ is selected from the group consisting of: optionally substituted pyridinyl, optionally substituted pyridazinyl, optionally substituted pyrimidinyl, optionally substituted pyrazinyl, optionally substituted triazinyl, optionally substituted quinolinyl, optionally substituted isoquinolinyl, optionally substituted quinazolinyl, optionally substituted phthalazinyl, optionally substituted quinoxalinyl, optionally substituted naphthyridinyl, and optionally substituted purinyl.

In other embodiments, A⁰ and Aⁱ are each optionally substituted alkyl. In other embodiments, A⁰ and Aⁱ are each optionally substituted alkenyl. In some embodiments, at least one of the A⁰ and Aⁱ is selected from the group consisting of:

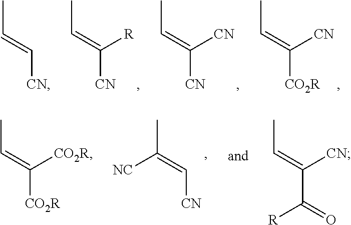

wherein R is optionally substituted alkyl.

In formula I-a and I-b, A² is selected from the group consisting of optionally substituted alkylene, optionally substituted alkenylene, optionally substituted arylene, optionally substituted heteroarylene, ketone, ester, and

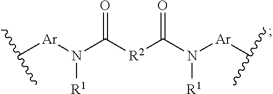

wherein Ar is optionally substituted aryl or optionally substituted heteroaryl. R¹ is selected from the group consisting of H, alkyl, alkenyl, aryl, heteroaryl, aralkyl, alkaryl; and R² is selected from the group consisting of optionally substituted alkylene, optionally substituted alkenylene, optionally substituted arylene, optionally substituted heteroarylene, ketone, and ester; or R¹ and R² may be connected together to form a ring.

In some embodiments, A² is selected from the group consisting of optionally substituted arylene, optionally substituted heteroarylene, and

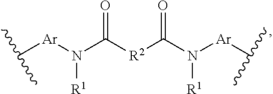

wherein Ar, R¹ and R² are as described above.

In formulae I-a and I-b, D¹ and D² are each independently selected from the group consisting of hydrogen, optionally substituted alkoxy, optionally substituted aryloxy, optionally substituted acyloxy, optionally substituted alkyl, optionally substituted aryl, optionally substituted heteroaryl, optionally substituted amino, amido, cyclic amido, and cyclic imido, provided that D¹ and D² are not both hydrogen.

In some embodiments, D¹ and D² are each independently selected from the group consisting of hydrogen, optionally substituted aryl, optionally substituted heteroaryl, and amino, provided that D¹ and D² are not both hydrogen. In some embodiments, D¹ and D² are each independently selected from the group consisting of hydrogen, optionally substituted aryl, optionally substituted heteroaryl, and diphenylamino, provided that D¹ and D² are not both hydrogen.

In some embodiments, D¹ and D² are each independently optionally substituted aryl. In some embodiments, D¹ and D² are each independently phenyl optionally substituted by alkoxy or amino. In other embodiments, D¹ and D² are each independently selected from hydrogen, optionally substituted benzofuranyl, optionally substituted thiophenyl, optionally substituted furanyl, dihydrothienodioxinyl, optionally substituted benzothiophenyl, and optionally substituted dibenzothiophenyl, provided that D¹ and D² are not both hydrogen.

In some embodiments, the substituent for optionally substituted aryl and optionally substituted heteroaryl may be selected from the group consisting of alkoxy, aryloxy, aryl, heteroaryl, and amino.

In formulae I-a and I-b, Lⁱ is independently selected from the group consisting of optionally substituted alkylene, optionally substituted alkenylene, optionally substituted alkynylene, optionally substituted arylene, optionally substituted heteroarylene. In some embodiments, Lⁱ is selected from the group consisting of optionally substituted heteroarylene and optionally substituted arylene.

In some embodiments, at least one of the Lⁱ is selected from the group consisting of: 1,2-ethylene, acetylene, 1,4-phenylene, 1,1′-biphenyl-4,4═-diyl, naphthalene-2,6-diyl, naphthalene-1,4-diyl, 9H-fluorene-2,7-diyl, perylene-3,9-diyl, perylene-3,10-diyl, or pyrene-1,6-diyl, 1H-pyrrole-2,5-diyl, furan-2,5-diyl, thiophen-2,5-diyl, thieno[3,2-b]thiophene-2,5-diyl, benzo[c]thiophene-1,3-diyl, dibenzo[b,d]thiophene-2,8-diyl, 9H-carbozole-3,6-diyl, 9H-carbozole-2,7-diyl, dibenzo[b,d]furan-2,8-diyl, 10H-phenothiazine-3,7-diyl, and 10H-phenothiazine-2,8-diyl; wherein each moiety is optionally substituted.

### Formulae II-a and II-b

Some embodiments provide a chromophore having one of the structures below:

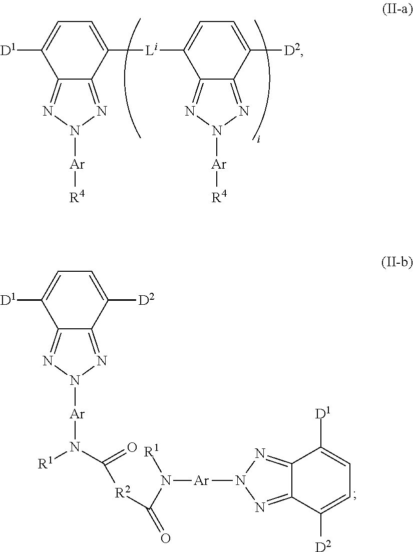

wherein i is an integer in the range of 0 to 100. In some embodiments, i is an integer in the range of 0 to 50, 0 to 30, 0 to 10, 0 to 5, or 0 to 3. In some embodiments, i is 0, 1, 2, 3, 4, 5, 6, 7, 8, 9, or 10.

In formulae II-a and II-b, Ar is optionally substituted aryl or optionally substituted heteroaryl. In some embodiments, aryl substituted with an amido or a cyclic imido group at the N-2 position of the 2H-benzo[d][1,2,3]triazole ring system provides unexpected and improved benefits.

In formulae II-a and II-b, R⁴ is

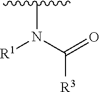

or optionally substituted cyclic imido; R¹ is each independently selected from the group consisting of H, alkyl, alkenyl, aryl, heteroaryl, aralkyl, alkaryl; R³ is each independently selected from the group consisting of optionally substituted alkyl, optionally substituted alkenyl, optionally substituted aryl, optionally substituted heteroaryl; or R′ and R″ may be connected together to form a ring.

In some embodiments, R⁴ is optionally substituted cyclic imido selected from the group consisting of:

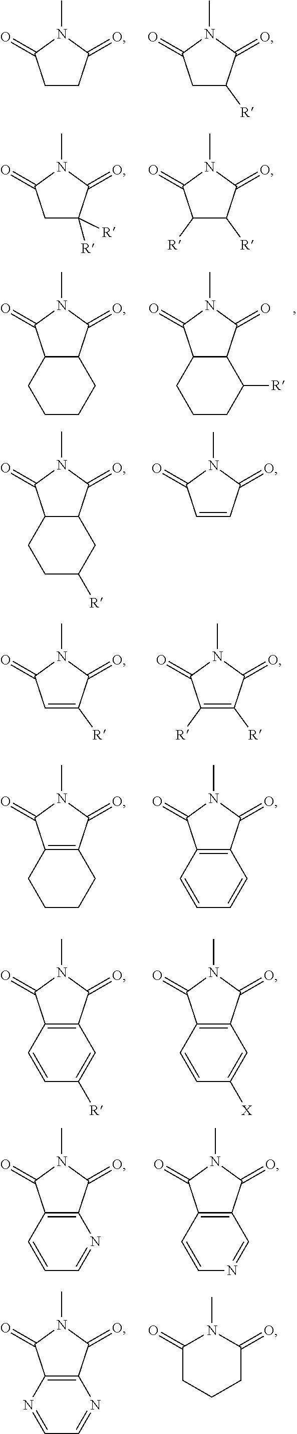

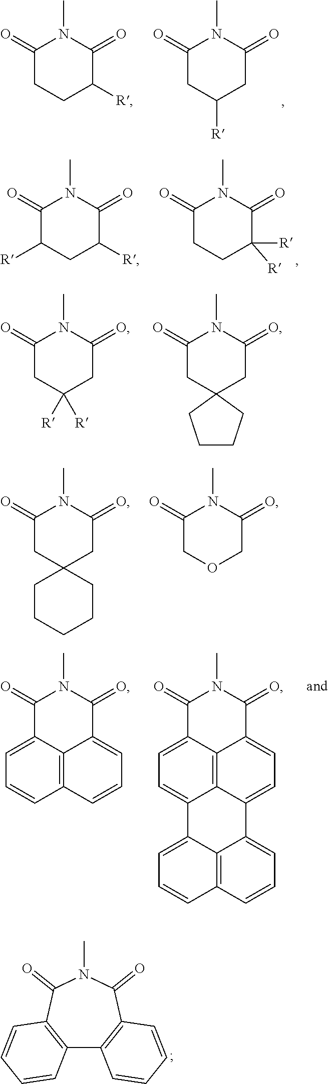

and wherein R′ is each optionally substituted alkyl or optionally substituted aryl; and X is optionally substituted hetero alkyl.

In formulae II-a and II-b, R² is selected from the group consisting of optionally substituted alkylene, optionally substituted alkenylene, optionally substituted arylene, optionally substituted heteroarylene.

In formulae II-a and II-b, D¹ and D² are each independently selected from the group consisting of hydrogen, optionally substituted alkoxy, optionally substituted aryloxy, optionally substituted acyloxy, optionally substituted alkyl, optionally substituted aryl, optionally substituted heteroaryl, optionally substituted amino, amido, cyclic amido, and cyclic imido, provided that D¹ and D² are not both hydrogen.

In formulae II-a and II-b, L¹ is independently selected from the group consisting of optionally substituted alkylene, optionally substituted alkenylene, optionally substituted alkynylene, optionally substituted arylene, optionally substituted heteroarylene.

In some embodiments, at least one of the L¹ is selected from the group consisting of: 1,2-ethylene, acetylene, 1,4-phenylene, 1,1′-biphenyl-4,4′-diyl, naphthalene-2,6-diyl, naphthalene-1,4-diyl, 9H-fluorene-2,7-diyl, perylene-3,9-diyl, perylene-3,10-diyl, or pyrene-1,6-diyl, 1H-pyrrole-2,5-diyl, furan-2,5-diyl, thiophen-2,5-diyl, thieno[3,2-b]thiophene-2,5-diyl, benzo[c]thiophene-1,3-diyl, dibenzo[b,d]thiophene-2,8-diyl, 9H-carbozole-3,6-diyl, 9H-carbozole-2,7-diyl, dibenzo[b,d]furan-2,8-diyl, 10H-phenothiazine-3,7-diyl, and 10H-phenothiazine-2,8-diyl; wherein each moiety is optionally substituted.

### Formulae III-a and III-b

Some embodiments provide a chromophore having one of the structures below:

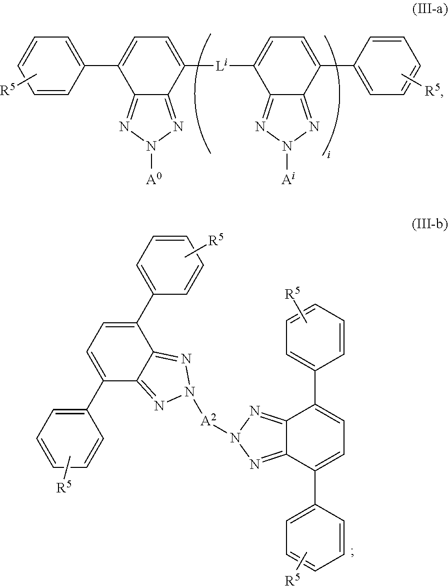

The placement of an alkyl group in formulae (III-a) and (III-b) at the N-2 position of the 2H-benzo[d][1,2,3]triazole ring system along with substituted phenyls at the C-4 and C-7 positions provides unexpected and improved benefits. In formula III-a and III-b, i is an integer in the range of 0 to 100. In some embodiments, i is an integer in the range of 0 to 50, 0 to 30, 0 to 10, 0 to 5, or 0 to 3. In some embodiments, i is 0, 1, 2, 3, 4, 5, 6, 7, 8, 9, or 10.

In formula III-a and III-b, A⁰ and Aⁱ are each independently selected from the group consisting of optionally substituted alkyl, optionally substituted alkenyl, optionally substituted heteroalkyl, optionally substituted amido, optionally substituted alkoxy, optionally substituted cabonyl, and optionally substituted carboxy.

In some embodiments, A⁰ and Aⁱ are each independently unsubstituted alkyl or alkyl substituted by a moiety selected from the group consisting of: —NRR″, —OR, —COOR, —COR, —CONHR, —CONRR″, halo and —CN; wherein R is C₁-C₂₀ alkyl, and R″ is hydrogen or C₁-C₂₀ alkyl. In some embodiments, the optionally substituted alkyl may be optionally substituted C₁-C₄₀ alkyl. In some embodiments, A⁰ and the Aⁱ are each independently C₁-C₄₀ alkyl or C₁-C₂₀ haloalkyl.

In some embodiments, A⁰ and Aⁱ are each independently C₁-C₂₀ haloalkyl, C₁-C₄₀ arylalkyl, or C₁-C₂₀ alkenyl.

In formulae III-a and III-b, each R⁵ is independently selected from the group consisting of optionally substituted alkoxy, optionally substituted aryloxy, optionally substituted acyloxy, and amino. In some embodiments, R⁵ may attach to phenyl ring at ortho and/or para position. In some embodiments, R⁵ may be alkoxy represented by the formula OCₙH₂₊₁ where n=1-40. In some embodiments, R⁵ may be aryloxy represented by the following formulae: ArO or O—CR—OAr where R is alkyl, substituted alkyl, aryl, or heteroaryl, and Ar is any substituted or unsubstituted aryl, or substituted or unsubstituted heteroaryl. In some embodiments, R⁵ may be acyloxy represented by the formula OCOCₙH₂₊₁ where n=1-40.

In formulae III-a and III-b, A² is selected from the group consisting of optionally substituted alkylene, optionally substituted alkenylene, optionally substituted arylene, optionally substituted heteroarylene, ketone, ester, and

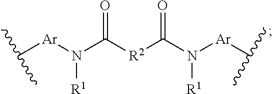

wherein Ar is optionally substituted aryl or optionally substituted heteroaryl, R¹ is selected from the group consisting of H, alkyl, alkenyl, aryl, heteroaryl, aralkyl, alkaryl; and R² is selected from the group consisting of optionally substituted alkylene, optionally substituted alkenylene, optionally substituted arylene, optionally substituted heteroarylene, ketone, and ester; or R¹ and R² may be connected together to form a ring.

In formulae III-a and III-b, Lⁱ is independently selected from the group consisting of optionally substituted alkylene, optionally substituted alkenylene, optionally substituted alkynylene, optionally substituted arylene, optionally substituted heteroarylene.

In some embodiments, at least one of the Lⁱ is selected from the group consisting of: 1,2-ethylene, acetylene, 1,4-phenylene, 1,1′-biphenyl-4,4′-diyl, naphthalene-2,6-diyl, naphthalene-1,4-diyl, 9H-fluorene-2,7-diyl, perylene-3,9-diyl, perylene-3,10-diyl, or pyrene-1,6-diyl, 1H-pyrrole-2,5-diyl, furan-2,5-diyl, thiophen-2,5-diyl, thieno[3,2-b]thiophene-2,5-diyl, benzo[c]thiophene-1,3-diyl, dibenzo[b,d]thiophene-2,8-diyl, 9H-carbozole-3,6-diyl, 9H-carbozole-2,7-diyl, dibenzo[b,d]furan-2,8-diyl, 10H-phenothiazine-3,7-diyl, and 10H-phenothiazine-2,8-diyl; wherein each moiety is optionally substituted.

### Formula IV

Some embodiments provide a chromophore having the structure below:

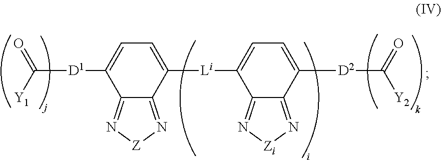

wherein i is an integer in the range of 0 to 100. In some embodiments, i is an integer in the range of 0 to 50, 0 to 30, 0 to 10, 0 to 5, or 0 to 3. In some embodiments, i is 0, 1, 2, 3, 4, 5, 6, 7, 8, 9, or 10.

In formula IV, Z and Zᵢ are each independently selected from the group consisting of —O—, —S—, —Se—, —Te—, —NR⁶—, —CR⁶═CR⁶—, and —CR⁶═N—, wherein R⁶ is hydrogen, optionally substitute C₁-C₆ alkyl, or optionally substituted C₁-C₁₀ aryl; and

In formula IV, D¹ and D² are independently selected from the group consisting of optionally substituted alkoxy, optionally substituted aryloxy, optionally substituted acyloxy, optionally substituted alkyl, optionally substituted aryl, optionally substituted heteroaryl, optionally substituted amino, amido, cyclic amido, and cyclic imido; j is 0, 1 or 2, and k is 0, 1, or 2. In some embodiments, the —C(═O)Y₁ and —C(═O)Y₂ groups may attach to the substituent(s) of the optionally substituted moiety for D¹ and D².

In formula IV, Y₁ and Y₂ are independently selected from the group consisting of optionally substituted aryl, optionally substituted alkyl, optionally substituted cycloalkyl, optionally substituted alkoxy, and optionally substituted amino; and

In formula IV, Lⁱ is independently selected from the group consisting of optionally substituted alkylene, optionally substituted alkenylene, optionally substituted alkynylene, optionally substituted arylene, optionally substituted heteroarylene.

In some embodiments, at least one of the Lⁱ is selected from the group consisting of: 1,2-ethylene, acetylene, 1,4-phenylene, 1,1′-biphenyl-4,4′-diyl, naphthalene-2,6-diyl, naphthalene-1,4-diyl, 9H-fluorene-2,7-diyl, perylene-3,9-diyl, perylene-3,10-diyl, or pyrene-1,6-diyl, 1H-pyrrole-2,5-diyl, furan-2,5-diyl, thiophen-2,5-diyl, thieno[3,2-b]thiophene-2,5-diyl, benzo[c]thiophene-1,3-diyl, dibenzo[b,d]thiophene-2,8-diyl, 9H-carbozole-3,6-diyl, 9H-carbozole-2,7-diyl, dibenzo[b,d]furan-2,8-diyl, 10H-phenothiazine-3,7-diyl, and 10H-phenothiazine-2,8-diyl; wherein each moiety is optionally substituted.

With regard to Lⁱ in any of the formulae above, the electron linker represents a conjugated electron system, which may be neutral or serve as an electron donor itself. In some embodiments, some examples are provided below, which may or may not contain additional attached substituents.

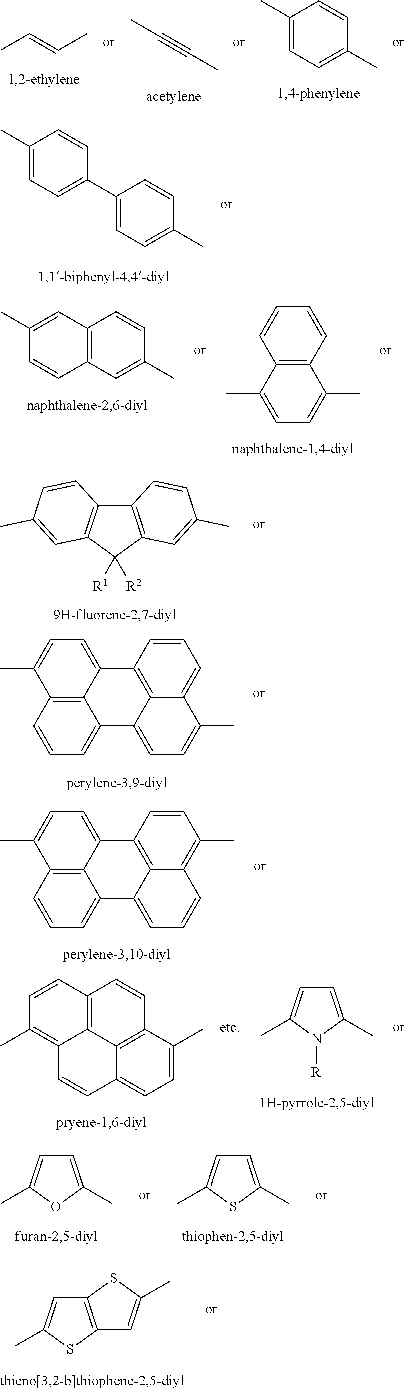

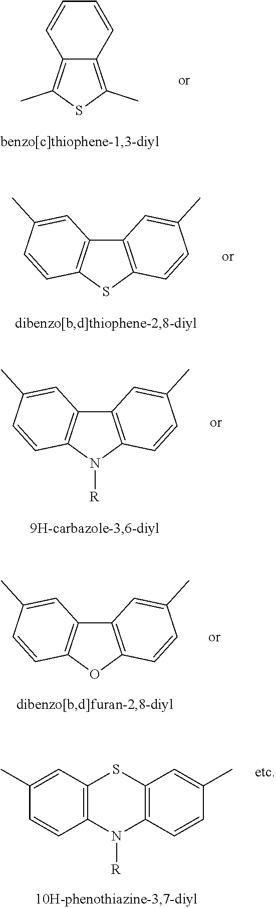

### Formulae V-a and V-b

Some embodiments provide a perylene diester derivative represented by the following general formula (V-a) or general formula (V-b):

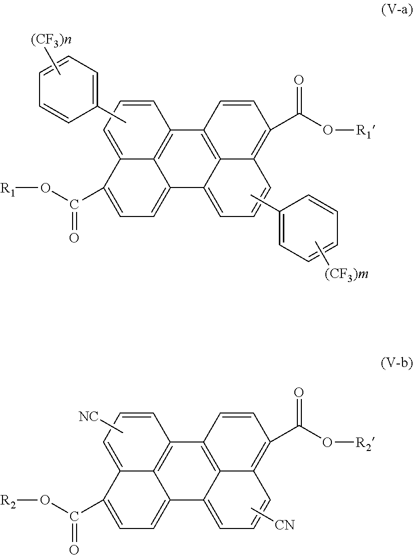

wherein R₁ and R₁′ in formula (V-a) are each independently selected from the group consisting of hydrogen, C₁-C₁₀ alkyl, C₃-C₁₀ cycloalkyl, C₁-C₁₀ alkoxy, C₆-C₁₈ aryl, and C₆-C₂₀ aralkyl; m and n in formula (V-a) are each independently in the range of from 1 to 5; and R₂ and R₂′ in formula (V-b) are each independently selected from the group consisting of a C₆-C₁₈ aryl and C₆-C₂₀ aralkyl. In some embodiments, if one of the cyano groups on formula (V-b) is present on the 4-position of the perylene ring, then the other cyano group is not present on the 10-position of the perylene ring. In some embodiments, if one of the cyano groups on formula (V-b) is present on the 10-position of the perylene ring, then the other cyano group is not present on the 4-position of the perylene ring.

In some embodiments, R₁ and R₁′ are independently selected from the group consisting of hydrogen, C₁-C₆ alkyl, C₂-C₆ alkoxyalkyl, and C₆-C₁₈ aryl. In some embodiments, R₁ and R₁′ are each independently selected from the group consisting of isopropyl, isobutyl, isohexyl, isooctyl, 2-ethyl-hexyl, diphenylmethyl, trityl, and diphenyl. In some embodiments, R₂ and R₂′ are independently selected from the group consisting of diphenylmethyl, trityl, and diphenyl. In some embodiments, each m and n in formula (V-a) is independently in the range of from 1 to 4.

The perylene diester derivative represented by the general formula (V-a) or general formula (V-b) can be made by known methods, such as those described in International Publication No. WO 2012/094409, the contents of which are hereby incorporated by reference in their entirety.

In some embodiments, the at least one photostable chromophore is present in the polymer matrix of the pressure sensitive adhesive layer in an amount in the range of about 0.01 wt % to about 10.0 wt %, by weight of the polymer matrix. In some embodiments, the at least one photostable chromophore is present in the polymer matrix of the pressure sensitive adhesive layer in an amount in the range of about 0.01 wt % to about 3.0 wt %, by weight of the polymer matrix. In some embodiments, the at least one photostable chromophore is present in the polymer matrix of the pressure sensitive adhesive layer in an amount in the range of about 0.05 wt % to about 2.0 wt %, by weight of the polymer matrix. In some embodiments, the at least one chromophore is present in the polymer matrix of the pressure sensitive adhesive layer in an amount in the range of about 0.1 wt % to about 1.0 wt %, by weight of the polymer matrix.

In some embodiments, the pressure sensitive adhesive layer comprises more than one chromophore, for example, at least two different chromophores. It may be desirable to have multiple photostable chromophores in the pressure sensitive adhesive layer, depending on the solar module that the tape is to be attached. For example, in a solar module system having an optimum photoelectric conversion at about 500 nm wavelength, the efficiency of such a system can be improved by converting photons of other wavelengths into 500 nm wavelengths. In such instance, a first photostable chromophore may act to convert photons having wavelengths in the range of about 400 nm to about 450 nm into photons of a wavelength of about 500 nm, and a second photostable chromophore may act to convert photons having wavelengths in the range of about 450 nm to about 475 nm into photons of a wavelength of about 500 nm. Particular wavelength control may be selected based upon the chromophore(s) utilized.

In some embodiments, two or more chromophores are mixed together within the same layer, such as, for example, in the pressure sensitive adhesive layer. In some embodiments, two or more chromophores are located in separate layers or sublayers within the wavelength conversion tape. For example, the pressure sensitive adhesive layer can comprise a first chromophore, and an additional polymer sublayer in between the substrate and the pressure sensitive adhesive layer, can comprise a second chromophore.

Chromophores can be up-converting or down-converting. In some embodiments, the at least one chromophore may be an up-conversion chromophore, meaning a chromophore that converts photons from lower energy (long wavelengths) to higher energy (short wavelengths). In some embodiments, the at least one chromophore may be a down-shifting chromophore, meaning a chromophore that converts photons of high energy (short wavelengths) into lower energy (long wavelengths). In some embodiments, the wavelength conversion tape comprises both an up-conversion chromophore and a down-shifting chromophore.

Various types of adhesives may be used in the pressure sensitive adhesive layer. In some embodiments, the adhesive polymeric material in the pressure sensitive adhesive layer comprises a substance selected from the group consisting of rubber, acrylic, silicone, vinyl alkyl ether, polyester, polyamide, urethane, fluorine, epoxy, ethylene vinyl acetate, and combinations thereof. In some embodiments, the polymer matrix of the pressure sensitive adhesive layer is crosslinked using a crosslinking agent. The pressure sensitive adhesive can be permanent or non-permanent.

The pressure sensitive adhesive type of wavelength conversion tape may comprise various additional components. In some embodiments, the composition of the tape further comprises any one or more of the following components: various thickeners such as phenol resin, terpene-phenol-resin, terpene resin, xylene resin, rosin and hydrogenated resin, inorganic fillers such as calcium carbonate and carbon black, a lubricant, an age resistor, a dye, a colorant, a pigment, a surfactant, a plasticizer, an antifoaming agent, a flame retardant, a light stabilizer, a thixotropy agent, an ultraviolet absorbent, a low-molecular weight polymer, an antioxidant, a heat-resistant stabilizer, a metal powder, a polymerization inhibitor, and any mixture thereof.

Preferably, the material used in either the pressure sensitive adhesive layer, the substrate, or both, has a refractive index in the range of about 1.4 to about 1.7. In some embodiments, the refractive index of the material used in the pressure sensitive adhesive layer, the substrate, or both, is in the range of about 1.45 to about 1.55.

Synthetic methods for the pressure sensitive adhesive type of wavelength conversion tape are not restricted, but may follow the synthetic procedures described below. Procedures for forming pressure sensitive adhesive type of tapes, without wavelength conversion properties, has been described in the literature, for example, see U.S. Pat. Nos. 7,867,601 and 7,887,914. Methods for forming the pressure sensitive adhesive type of wavelength conversion tape may follow similar methods to that described in these patents, with the exception of the addition of a luminescent dye to the composition used to form the pressure sensitive adhesive layer, and any additional components and/or processes required to ensure the wavelength conversion integrity of the tape. For example, for some embodiments, only low temperature processing may be used to form the tape, as heat may degrade the chromophore compound. Also, for some embodiments, only solvents which do not react with and/or degrade the chromophore, may be used to form the tape.

In some embodiments, a pressure sensitive adhesive layer is formed by dissolving known adhesive polymeric materials into a polymer solution using a solvent. Polymeric pressure sensitive adhesives may include, for example, rubber, acrylic, silicone, vinyl alkyl ether, polyester, polyamide, urethane, fluorine, epoxy, ethylene vinyl acetate, or a mixture thereof.

Examples of the solvent used to form the polymer solution containing the pressure sensitive adhesives include aromatic hydrocarbon solvents such as toluene and xylene; aliphatic carboxylic acid ester solvents such as ethyl acetate and butyl acetate; aliphatic hydrocarbon solvents such as hexane, heptane, and octane; and ketone solvents such as acetone, methyl ethyl ketone, and methyl isobutyl ketone; and solvents such as dioxane, anisole, tetrachloroethylene, and cyclopentanone. These solvents may be used alone, or two or more of them may be used by mixing.

The content by percentage of the solvent in the polymer solution is usually from about 10 to 80% by weight. One or more luminescent dyes may be added to the polymer solution in the amount 0.01 wt % to 10.0 wt % of each chromophore, by weight of the polymer matrix.

Besides the above mentioned components, the following can be appropriately used as optional components in the polymer solution: various thickeners such as phenol resin, terpene-phenol resin, terpene resin, xylene resin, rosin, and hydrogenated rosin, inorganic fillers such as calcium carbonate and carbon black, a lubricant, an age resistor, a dye, a colorant, a pigment, a surfactant, a plasticizer, an antifoaming agent, a flame retardant, a light stabilizer, a thixotropy agent, an ultraviolet absorbent, a low-molecular-weight polymer, a surface-lubricating agent, a leveling agent, an antioxidant, a polymerization inhibitor, a heat-resistant stabilizer, a hydrolysis-resistant stabilizer, a metal powder, and a granule-form, or foil-form substance. These optional components may be used alone, or two or more of them may be used by mixing.

The method for applying the pressure sensitive adhesive is not especially limited, and may be appropriately selected from ordinarily used methods. For example, in some embodiments, a coater is used to apply a solution of the pressure sensitive adhesive onto the substrate, and then the solvent is removed therefrom, whereby a pressure sensitive adhesive layer can be formed. In some embodiments, a crosslinking agent is added to the polymer solution of the pressure sensitive adhesive, and then the resultant is heated and crosslinked to set the pressure sensitive adhesive polymer therein, whereby a pressure sensitive adhesive layer can be formed.

In some embodiments, the crosslinking agent used in the invention may be an isocyanate compound, an epoxy compound, a melamine-based resin, an aziridine derivative, a metal chelate compound, or the like. Particularly preferable is an isocyanate or epoxy compound since the compound gives an appropriate cohesive strength. It is particularly preferable that at the time of the production of a polymer, the polymer is copolymerized with a hydroxyl containing monomer such as 2-hydroxyethyl acrylate so as to introduce the hydroxyl group into the polymer and then a polyisocyanate compound is used as a crosslinking agent for this polymer. These compounds may be used alone, or two or more of them may be used by mixing.

Examples of the isocyanate compound include low aliphatic polyisocyanates such as butylene diisocyanate and hexamethylene diisocyanate; alicyclic isocyanates such as cyclopentylene diisocyanate, cyclohexylene diisocyanate, and isophrone diisocyanate; aromatic isocyanates such as 2,4-tolylene diisocyanate, 4,4′-diphenylmethane diisocyanate, and xylylene diisocyanate; isocyanate adducts such as a trimethylolpropane/tolylene diisocyanate trimer adduct, a trimethylolpropane/hexamethylene diisocyanate trimer adduct, and an isocyanurate product of hexamethylene diisocyanate; and diisocyanate adducts to polyol. These compounds may be used alone, or two or more of them may be used by mixing.

Examples of the epoxy include N,N,N′,N′-tetraglycidyl-m-xylenediamine, and 1,3-bis(N,N-diglycidylaminomethyl)cyclohexane. These compounds may be used alone, or two or more of them may be used by mixing.

An example of the melamine-based resin is hexamethylolmelamine.

Examples of the aziridine derivative include commercially available products manufactured by Sogo Pharmaceutical Co., Ltd. (trade names: HDU, TAZM and TAZO). These compounds may be used alone, or two or more of them may be used by mixing.

Examples of the metal chelate compound include compounds wherein the metal component thereof is aluminum, iron, tin, titanium, or nickel, and the chelate component thereof is acetylene, methyl acetoacetate, or ethyl lactate. These compounds may be used alone, or two or more of them may be used by mixing.

The content of the crosslinking agent used in the invention is usually from about 0.01 to 5 parts by weight for 100 parts by weight of the base polymer such as (meth)acrylate-based polymer.

The thickness of the pressure sensitive adhesive layer used in the invention is preferably from about 1 μm to about 500 μm, more preferably from about 100 μm to about 200 μm after the adhesive layer is dried. If the thickness is less than 1 μm, the adhesive strength to an adherend is insufficient. If the thickness is more than about 500 μm, the adhesive strength is saturated so that economical efficiency is lost. Moreover, the adhesive is pushed out, or cohesion breakdown is caused so that the tape is not easily peeled.

The method for forming the pressure sensitive adhesive layer of the tape is not especially limited. In some embodiments, the layer is formed by, for example, a method of applying the pressure sensitive adhesive onto the substrate, and drying and removing the polymerization solvent and others therein to form the pressure sensitive adhesive layer on the substrate, or a method of applying the pressure sensitive adhesive onto another substrate, drying and removing the polymerization solvent and others therein, and then transferring/forming the pressure sensitive adhesive layer onto the substrate layer of the tape. After the formation of the pressure sensitive adhesive layer, the layer may be cured for the adjustment of the shift of the components in the pressure sensitive adhesive layer, the adjustment of the crosslinking reaction, and others. When the pressure sensitive adhesive is applied onto the substrate to form a pressure sensitive adhesive tape, one or more solvents other than the polymerization solvent may be newly added to the composition so that the adhesive can be evenly applied onto the substrate.

In some embodiments, the method for forming the pressure sensitive adhesive layer may be appropriately selected from known methods used to produce a pressure sensitive adhesive layer. Specific examples thereof include roll coating, kiss roll coating, gravure coating, reverse coating, roll brush coating, spray coating, dip roll coating, bar coating, knife coating, and air knife coating.

In some embodiments, the pressure sensitive adhesive type of wavelength conversion tape of the invention is, for example, a tape comprising a substrate and a pressure sensitive adhesive wherein the adhesive is laminated on the substrate.

If necessary, the substrate may be subjected to, for example, releasing or antifouling treatment with a silicone type, fluorine-containing type, long chain alkyl type or aliphatic acid amide type releasing agent, or silica powder, an adhesion-promoting treatment such as acid treatment, alkali treatment, primer treatment, anchor coat treatment, corona treatment, plasma treatment or ultraviolet treatment, or an antistatic treatment such as coating type, kneading type or vapor-deposition type treatment.

In some embodiments, the substrate layer may comprise a polymer material. In some embodiments, the substrate is optically transparent. In some embodiments, the substrate layer comprises a polymer matrix. In some embodiments, the polymer matrix of the substrate layer is formed from a substance selected from the group consisting of polyethylenes, polypropylenes, polyester, polyamide, polycarbonate, polymethyl methacrylate, polyvinyl butyral, ethylene vinyl acetate, ethylene tetrafluoroethylene, polyimide, polystyrene, siloxane sol-gel, polyurethane, polyacrylate, and combinations thereof. In some embodiments, the thickness of the substrate is between about 10 μm and about 1 mm.

The pressure sensitive adhesive type of wavelength conversion tape may further comprise a removable liner, wherein this removable liner is stuck on the pressure sensitive adhesive layer and is appropriately removed when the surface of the pressure sensitive adhesive layer is used. The removable liner used in the invention can be appropriately selected, without any especial limitation, from members which have been hitherto used as a removable liner. Specific examples of the removable liner include plastic films such as polyethylene, polypropylene, polyethylene terephthalate, and polyester films; paper products such as glassine paper, coated paper, and laminated paper products; porous material sheets such as cloth and nonwoven fabric sheets; and various thin bodies, such as a net, a foamed sheet, a metal foil, and laminates thereof. Any one of the plastic films is preferably used since it is excellent in surface flatness or smoothness. The film is not limited to any especial kind if the film can protect the pressure sensitive adhesive layer. In some embodiments, the removable liner consists of a material selected from fluoropolymers, polyethylene terephthalate, polyethylene, polypropylene, polyester, polybutene, polybutadiene, polymethylpentene, polyvinyl chloride, vinyl chloride copolymer, polybutalene terepthalate, polyurethane, ethylene-vinyl acetate, glassine paper, coated paper, laminated paper, cloth, nonwoven fabric sheets, or metal foil. In some embodiments, the thickness of the removable liner is between about 10 μm and about 100 μm.

The total thickness of the pressure sensitive adhesive type of wavelength conversion tape can be represented by adding the thicknesses of each individual film described herein. In some embodiments, the thickness of the wavelength conversion tape is in the range of about 10 μm to about 2 mm. In some embodiments, the thickness of the wavelength conversion tape is in the range of about 1 μm to about 5 mm. In some embodiments, the thickness of the wavelength conversion film is in the range of about 50 μm to about 1 mm.

The pressure sensitive adhesive type of wavelength conversion tape may also comprise additional layers. For example, additional polymer films, or adhesive layers may be included. In some embodiments, the tape further comprises an additional polymer layer containing a UV absorber, which may act to block high energy irradiation and prevent photo-degradation of the chromophore compound. Other layers may also be included to further enhance the photoelectric conversion efficiency of solar modules. For example, the tape may additionally have a microstructured layer on top of the substrate layer or in between the substrate and the pressure sensitive adhesive layer, which is designed to further enhance the solar harvesting efficiency of solar modules by decreasing the loss of photons to the environment which are often re-emitted from the chromophore after absorption and wavelength conversion in a direction that is away from the photoelectric conversion layer of the solar module device. A layer with various microstructures on the surface (i.e. pyramids or cones) may increase internal reflection and refraction of the photons into the photoelectric conversion layer of the device, further enhancing the solar harvesting efficiency of the device. Additional layers may also be incorporated into the pressure sensitive adhesive type of wavelength conversion tape.

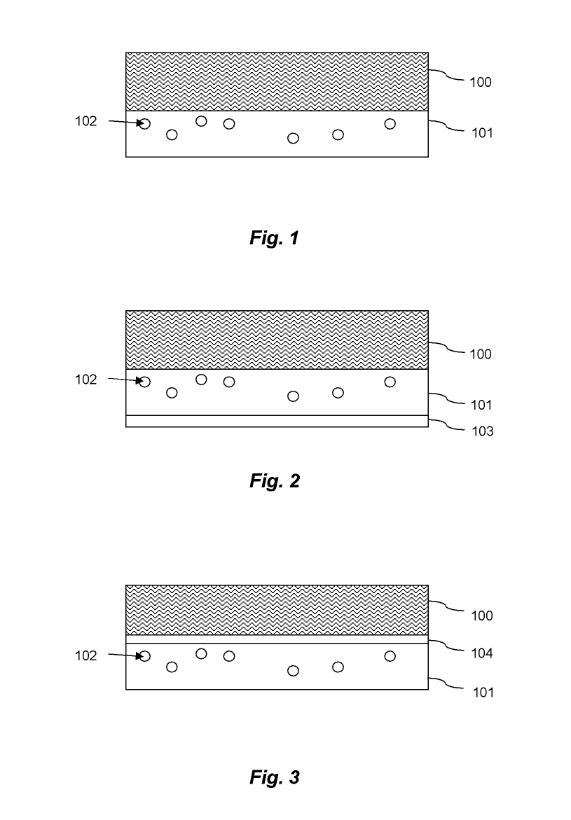

In some embodiments as shown in FIG. 1, the pressure sensitive adhesive type of wavelength conversion tape comprises a substrate 100 and a pressure sensitive adhesive layer 101, wherein the pressure sensitive adhesive layer comprises an adhesive polymeric material and at least one luminescent dye 102.

In some embodiments as shown in FIG. 2, the pressure sensitive adhesive type of wavelength conversion tape comprises a substrate 100, a pressure sensitive adhesive layer 101, and a removable liner 103, wherein the pressure sensitive adhesive layer comprises an adhesive polymeric material and at least one luminescent dye 102.

In some embodiments as shown in FIG. 3, the pressure sensitive adhesive type of wavelength conversion tape comprises a substrate 100, a pressure sensitive adhesive layer 101, and an additional polymer layer 104, wherein the pressure sensitive adhesive layer comprises an adhesive polymeric material and at least one luminescent dye 102.

In another aspect of the invention, a method of improving the performance of a solar cell, a solar panel, or photovoltaic device comprises applying the pressure sensitive adhesive type of wavelength conversion tape, disclosed herein, to a solar cell, solar panel, or photovoltaic device. In some embodiments of the method, the tape is applied to the solar cell, solar panel, or photovoltaic device, using a roll laminator. Devices, such as a Silicon based device, a III-V or II-VI PN junction device, a Copper-Indium-Gallium-Selenium (CIGS) thin film device, an organic sensitizer device, an organic thin film device, or a Cadmium Sulfide/Cadmium Telluride (CdS/CdTe) thin film device, can be improved.

Solar harvesting devices commonly use glass or polymer materials to encapsulate or protect the device, and this material is typically exposed to the environment on the light incident side of the device. Therefore, the pressure sensitive adhesive type of wavelength conversion tape must be compatible to adhere to these types of glass and polymer surfaces. In some embodiments of the method, the light incident surface of the solar cell, solar panel, or photovoltaic device is a material consisting of glass or polymer. In some embodiments of the method, the adhesive layer of the tape is designed to adhere to glass surfaces. In some embodiments of the method, the adhesive layer of the tape is designed to adhere to polymer surfaces.

Solar harvesting devices may also be rigid or flexible. Rigid devices include Silicon based solar cells. Flexible solar devices are often made out of organic thin films and may be used on clothing, tents, or other flexible substrates. Therefore, in some embodiments, the pressure sensitive adhesive type of wavelength conversion tape can be applied to rigid devices or flexible devices.

In some embodiments, the pressure sensitive adhesive type of wavelength conversion tape is applied to a rigid solar panel using a roll laminator to peel away the liner and unroll the tape, and then press the tape onto the incident surface of a solar panel. As the wavelength conversion tape is unrolled, the tape may be partially cut according to the size of the surface to be covered by the tape, leaving the liner intact. As the roller unroll the tape, the uncut liner is wound onto another roller, while the tape portion is applied to the surface of a solar panel.

In some embodiments, the pressure sensitive adhesive type of wavelength conversion tape is applied to a flexible solar panel device using a roll laminator to peel away the liner and unroll the tape, and then press the tape onto the solar panel as described above. The laminated flexible solar panel can also be wound after the application of the tape.

The object of this current invention is to provide a pressure sensitive adhesive type of wavelength conversion tape which may be suitable for application to solar cells, photovoltaic devices, solar modules, and solar panels. By using this film, we can expect improved light conversion efficiency.

Synthetic methods for forming the pressure sensitive wavelength conversion layer are not restricted, but may follow the example synthetic procedures described below.

In some embodiments, a pressure sensitive wavelength conversion layer 101, which comprises at least one luminescent dye, and an adhesive polymeric material, is fabricated onto a glass plate. The pressure sensitive wavelength conversion layer is fabricated by (i) preparing an 80 wt % Poly (butyl acetate-co-acetic acid) (BA/AA) polymer solution with dissolved polymer in toluene; (ii) preparing a chromophore containing a BA/AA matrix by mixing the BA/AA solution with the synthesized chromophore at a weight ratio (Chromophore/BA/AA) of 0.2 wt % to obtain a chromophore-containing adhesive polymer solution; (iii) forming the chromophore/polymer film by directly casting the chromophore-containing polymer solution onto a glass plate, then heat treating the plate in a vacuum oven at 150° C. for 1 hour to remove toluene, and (iv) then two specimens are attached together and manually pressed between two glass plates with 100 μm glass beads in between at 150° C. to obtain glass laminated with pressure sensitive wavelength conversion layer.

Once the pressure sensitive wavelength conversion layer is formed it can be adhered to the light incident surface of a solar cell. In some embodiments, a glass plate is used as a substrate for the pressure sensitive adhesive layer. In some embodiments, the substrate also acts as a protective layer, which protects the pressure sensitive adhesive layer from exposure to the environment.

For purposes of summarizing aspects of the invention and the advantages achieved over the related art, certain objects and advantages of the invention are described in this disclosure. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught herein without necessarily achieving other objects or advantages as may be taught or suggested herein.

Further aspects, features and advantages of this invention will become apparent from the detailed examples which follow.

### EXAMPLES

The embodiments will be explained with respect to preferred embodiments which are not intended to limit the present invention. Further, in the present disclosure where conditions and/or structures are not specified, the skilled artisan in the art can readily provide such conditions and/or structures, in view of the present disclosure, as a matter of routine experimentation.

### Synthesis of Chromophore Compounds

### Intermediate A

Common Intermediate A was synthesized according to the following scheme.

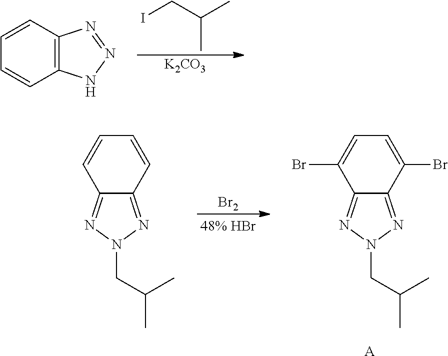

Step 1: 2-Isobutyl-2H-benzo[d][1,2,3]triazole.

A mixture of benzotriazole (11.91 g, 100 mmol), 1-iodo-2-methylpropane (13.8 mL, 120 mmol), potassium carbonate (41.46 g, 300 mmol), and dimethylformamide (200 mL) was stirred and heated under argon at 40° C. for 2 days. The reaction mixture was poured into ice/water (1 L) and extracted with toluene/hexanes (2:1, 2×500 mL). The extract was washed with 1 N HCl (2×200 mL) followed by brine (100 mL), dried over anhydrous magnesium sulfate, and the solvent was removed under reduced pressure. The residue was triturated with hexane (200 mL) and set aside at room temperature for 2 hours. The precipitate was separated and discarded, and the solution was filtered through a layer of silica gel (200 g). The silica gel was washed with hexane/dichloromethane/ethyl acetate (37:50:3, 2 L). The filtrate and washings were combined, and the solvent was removed under reduced pressure to give 2-isobutyl-2H-benzo[d][1,2,3]triazole (8.81 g, 50% yield) as an oily product. ¹H NMR (400 MHz, CDCl₃): δ 7.86 (m, 2H, benzotriazole), 7.37 (m, 2H, benzotriazole), 4.53 (d, J=7.3 Hz, 2H, i-Bu), 2.52 (m, 1H, i-Bu), 0.97 (d, J=7.0 Hz, 6H, i-Bu).

Step 2: 4,7-Dibromo-2-isobutyl-2H-benzo[d][1,2,3]triazole (Intermediate A).

A mixture of 2-isobutyl-2H-benzo[d][1,2,3]triazole (8.80 g, 50 mmol), bromine (7.7 mL, 150 mmol) and 48% HBr (50 mL) was heated at 130° C. for 24 hours under a reflux condenser connected with an HBr trap. The reaction mixture was poured into ice/water (200 mL), treated with 5 N NaOH (100 mL) and extracted with dichloromethane (2×200 mL). The extract was dried over anhydrous magnesium sulfate, and the solvent was removed under reduced pressure. A solution of the residue in hexane/dichloromethane (1:1, 200 mL) was filtered through a layer of silica gel and concentrated to give 4,7-dibromo-2-isobutyl-2H-benzo[d][1,2,3]triazole, Intermediate A (11.14 g, 63% yield) as an oil that slowly solidified upon storage at room temperature. ¹H NMR (400 MHz, CDCl₃): δ 7.44 (s, 2H, benzotriazole), 4.58 (d, J=7.3 Hz, 2H, i-Bu), 2.58 (m, 1H, i-Bu), 0.98 (d, J=6.6 Hz, 6H, i-Bu).

### Chromophore 1

Example Compound Chromophore 1 was synthesized according to the following reaction scheme.

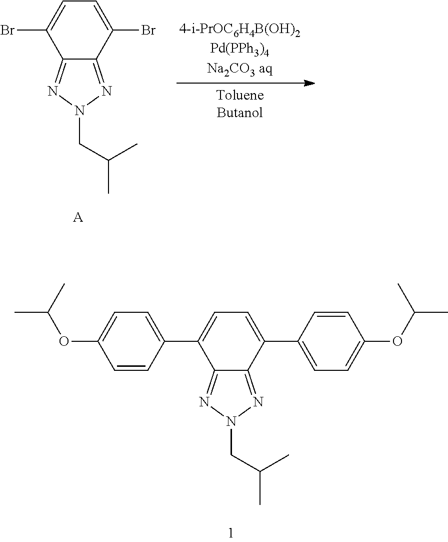

A mixture of Intermediate A (666 mg, 2.0 mmol), 4-isopropoxyphenylboronic acid (1.00 g, 5.5 mmol), tetrakis(triphenylphosphine)palladium(0) (0.50 g, 0.43 mmol), solution of sodium carbonate (1.06 g, 10 mmol) in water (8 mL), butanol (30 mL), and toluene (20 mL) was vigorously stirred and heated under argon at 100° C. for 20 hours. The reaction mixture was poured into water (300 mL), stirred for 30 minutes and extracted with toluene/ethyl acetate (1:1, 300 mL). The volatiles were removed under reduced pressure, and the residue was chromatographed (silica gel, hexane/dichloromethane, 1:1). The separated product was recrystallized from ethanol to give pure 4,7-bis(4-isopropoxyphenyl)-2-isobutyl-2H-benzo[d][1,2,3]triazole, Compound Chromophore 1 (655 mg, 74% yield). ¹H NMR (400 MHz, CDCl₃): δ 8.00 (d, J=8.7 Hz, 4H, 4-i-PrOC₆H₄), 7.55 (s, 2H, benzotriazole), 7.02 (d, J=8.8 Hz, 4H, 4-i-PrOC₆H₄), 4.64 (septet, J=6.2 Hz, 2H, 4-i-PrOC₆H₄), 4.59 (d, J=7.7 Hz, 2H, i-Bu), 2.61 (m, 1H, i-Bu), 1.38 (d, J=6.2 Hz, 12H, 4-i-PrOC₆H₄), 1.01 (d, J=6.6 Hz, 6H, i-Bu). UV-vis spectrum (PVB): λₘₐₓ=360 nm. Fluorimetry (PVB): λₘₐₓ=435 nm.

### Synthesis of Pressure Sensitive Adhesive Material

Poly (butyl acetate-co-acetic acid) (BA/AA) was used as the pressure sensitive adhesive material. The BA/AA material was synthesized according to the following reaction scheme.

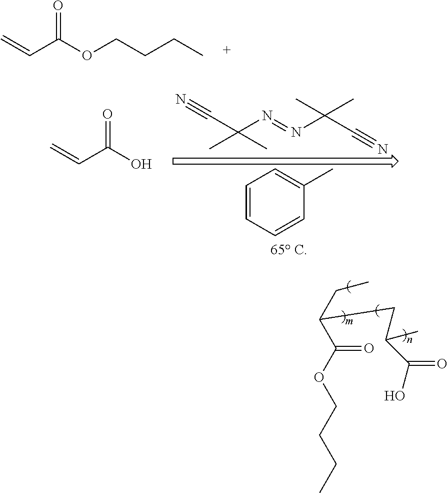

A 250 mL 2 neck reaction flask was equipped with argon flow and a condenser. To this flask, 53.1 mL (371 mmol, 1 eq) of the butyl acrylate was added. Then, 2.38 mL (34.7 mmol, 0.09 eq) of the acrylic acid was added, followed by addition of 166.7 mL of toluene. The reaction was stirred under argon for 10 minutes. As a final component, 135 mg (0.822 mmol, 0.002 eq) of AIBN initiator was added, and the reaction flask was immediately placed in a 65° C. pre-heated bath, and allowed to polymerize overnight. After polymerization, the reaction content was used as synthesized for testing.

### Example 1

### Synthesis of Pressure Sensitive Adhesive Wavelength Conversion Tape

Example 1 was fabricated according to the following procedure. A pressure sensitive wavelength conversion layer comprising a luminescent dye, and an adhesive polymeric material, is fabricated onto a glass plate. The pressure sensitive wavelength conversion layer is fabricated by (i) preparing an 80 wt % Poly (butyl acetate-co-acetic acid) (BA/AA) polymer solution with dissolved polymer in toluene; (ii) preparing a chromophore containing a BA/AA matrix by mixing the BA/AA solution with the synthesized Chromophore 1 at a weight ratio (Chromophore 1/BA/AA) of 0.2 wt % to obtain a chromophore-containing adhesive polymer solution; (iii) forming the chromophore/polymer film by directly casting the chromophore-containing polymer solution onto a B270 glass plate (2.5 cm×2.5 cm), then heat treating the plate in a vacuum oven at 150° C. for 1 hour to remove toluene, and (iv) then two specimens were attached together and manually pressed between two glass plates with 100 μm glass beads at 150° C. to obtain glass laminated with pressure sensitive wavelength conversion layer.

### Comparative Example 2

### Wavelength Conversion Film

Comparative Example 2 was fabricated according to the following procedure: (i) preparing an Ethylene vinyl acetate (EVA) polymer solution by dissolving a EVA powder (from Aldrich and used as received) in TCE (from Aldrich and used as received) at a predetermined ratio of 20 wt %; (ii) preparing a chromophore containing a EVA matrix by mixing the EVA polymer solution with the synthesized Compound Chromophore 1 at a weight ratio (Chromophore 1/EVA) of 0.3 wt % to obtain a chromophore-containing polymer solution; (iii) forming the chromophore/polymer layer by directly casting the chromophore-containing polymer solution onto a glass substrate, then heat treating the substrate from room temperature up to 100° C. in 2 hours, completely removing the remaining solvent by further vacuum heating at 130° C. overnight; and (iv) peeling off the chromophore/polymer layer under the water and then drying out the free-standing polymer layer; (v) the layer thickness was 250 μm, which was obtained by varying the chromophore/polymer solution concentration and evaporation speed. In Comparative Example 2, the EVA is not a pressure sensitive adhesive material.

### Application of Sample to Solar Cell

The Comparative Example 2 sample was applied to the light incident surface of a crystalline silicon solar cell by manually pressing the EVA/Chromophore film onto the light incident glass surface of the solar cell.

### Measurement of the Short Circuit Current Enhancement

The short circuit current enhancement is linearly proportional to the enhancement of the solar harvesting conversion efficiency, therefore, an increase in the short circuit current produced by the cell indicates that the solar harvesting efficiency is also increased. The solar cell photoelectric conversion efficiency of Comparative Example 2 was measured by a Newport 400 W full spectrum solar simulator system. The light intensity was adjusted to one sun (AM1.5 G) by a 2 cm×2 cm calibrated reference monocrystalline silicon solar cell. Then the I-V characterization of the crystalline silicon solar cell was performed under the same irradiation and its short circuit current is calculated by the Newport software program which is installed in the simulator. After determining the stand alone short circuit current of the cell, the enhancement of the cell with the Comparative Example 2 film is measured.

The short circuit current enhancement of the solar cell with the attached film was determined using the following equation:

Enhancement=(J_{cell+film}−J_{cell})/J_{cell}*100%

The relative enhancement for the crystalline silicon solar cell is ˜2-3% for Comparative Example 2 containing EVA and Chromophore Compound 1.

### Measurement of the Optical Properties

The absorption of the Example 1 and Comparative Example 2 samples were measured using a UV-Vis-NIR Spectrophotometer model UV-3600 from Shimadzu. The emission spectra of the Example 1 and Comparative Example 2 samples were measured on an Absolute PL Quantum Yield Spectrometer model C11347 from Hamamatsu.

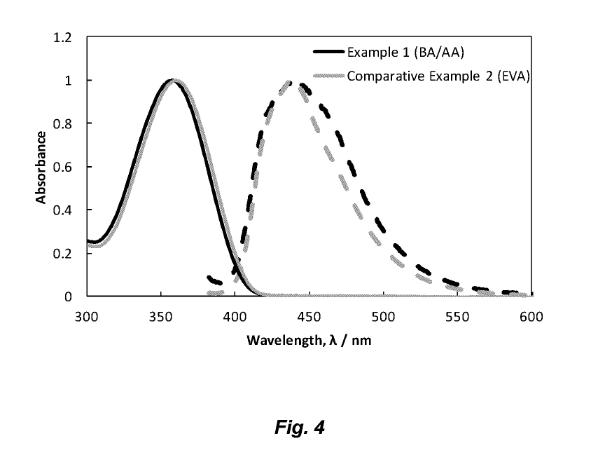

FIG. 4 shows the optical properties of the Example 1 and Comparative Example 2 samples. The absorption and emission of the films are very similar, indicating that the Example 1 film comprising the BA/AA as pressure sensitive adhesive with Chromophore 1 will have similar short circuit current improvement as Comparative Example 2, which was measured as ˜2-3% when applied to crystalline silicon solar cell.

The object of this current invention is to provide a pressure sensitive wavelength conversion tape which may be suitable for application to solar cells, photovoltaic devices, solar modules, and solar panels. As illustrated by the above examples, the application of a pressure sensitive wavelength conversion tape to the light incident surface of a solar harvesting device, can be expected to improve light conversion efficiency.

For purposes of summarizing aspects of the invention and the advantages achieved over the related art, certain objects and advantages of the invention are described in this disclosure. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught herein without necessarily achieving other objects or advantages as may be taught or suggested herein.

It will be understood by those of skill in the art that numerous and various modifications can be made without departing from the spirit of the present invention. Therefore, it should be clearly understood that the forms of the present invention are illustrative only and are not intended to limit the scope of the present invention.

1. A pressure sensitive wavelength conversion tape comprising:
a pressure sensitive adhesive layer, wherein the pressure sensitive adhesive layer comprises;
an adhesive polymeric material; and
at least one luminescent dye, wherein the at least one luminescent dye is configured to convert a portion of incoming photons of a first wavelength to a second wavelength.

2. The tape according to claim 1, further comprising a substrate layer, wherein the substrate layer comprises a polymer material.

3. The tape according to claim 1, wherein the pressure sensitive adhesive layer comprises two or more luminescent dyes.

4. The tape according to claim 1, wherein the at least one luminescent dye is an up-conversion chromophore.

5. The tape according to claim 1, wherein the at least one luminescent dye is a down-shifting chromophore.

6. The tape according to claim 1, wherein the at least one luminescent dye is an organic dye.

7. The tape according to claim 1, wherein the at least one luminescent dye is selected from the group consisting of perylene derivative dye, benzotriazole derivative dye, and benzothiadiazole derivative dye.

8. The tape according to claim 1, wherein the at least one luminescent dye is represented by formula (I-a) or (I-b): 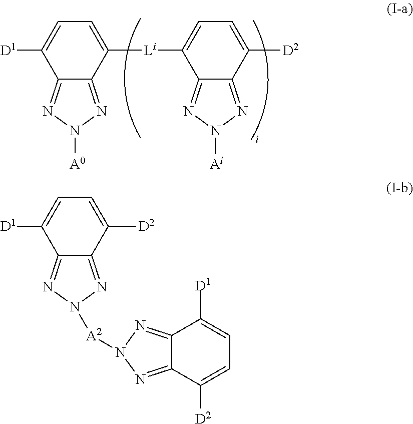
wherein:
i is an integer in the range of 0 to 100;
A⁰ and Aⁱ are each independently selected from the group consisting of optionally substituted alkyl, optionally substituted alkyenyl, optionally substituted heteroalkyl, optionally substituted aryl, optionally substituted heteroaryl, optionally substituted amino, optionally substituted amido, optionally substituted cyclo amido, optionally substituted cyclo imido, optionally substituted alkoxy, and optionally substituted carboxy, and optionally substituted carbonyl;
A² is selected from the group consisting of optionally substituted alkylene, optionally substituted alkenylene, optionally substituted arylene, optionally substituted heteroarylene, ketone, ester, and 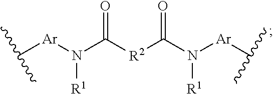
wherein Ar is optionally substituted aryl or optionally substituted heteroaryl; le is selected from the group consisting of H, alkyl, alkenyl, aryl, heteroaryl, aralkyl, alkaryl; and R² is selected from the group consisting of optionally substituted alkylene, optionally substituted alkenylene, optionally substituted arylene, optionally substituted heteroarylene, ketone, and ester; or R¹ and R² may be connected together to form a ring.
D¹ and D² are independently selected from the group consisting of hydrogen, optionally substituted alkoxy, optionally substituted aryloxy, optionally substituted acyloxy, optionally substituted alkyl, optionally substituted aryl, optionally substituted heteroaryl, optionally substituted amino, amido, cyclo amido, and cyclo imido, provided that D¹ and D² are not both hydrogen; and
Lⁱ is independently selected from the group consisting of optionally substituted alkylene, optionally substituted alkenylene, optionally substituted alkynylene, optionally substituted arylene, and optionally substituted heteroarylene.

9. The tape according to claim 1, wherein at least one luminescent dye is further represented by formula (II-a) or (II-b): 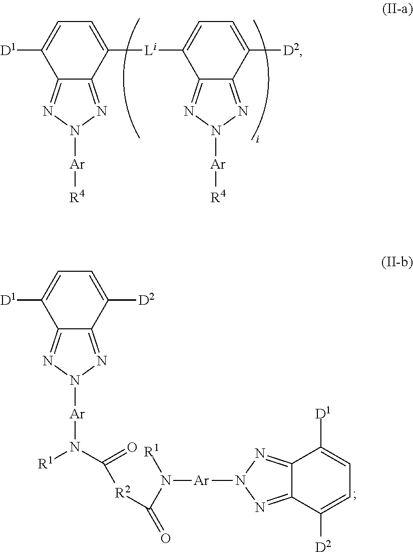
wherein:
i is an integer in the range of 0 to 100;
Ar is optionally substituted aryl or optionally substituted heteroaryl;
R⁴ is 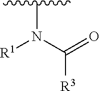
or optionally substituted cyclic imido;
R¹ is each independently selected from the group consisting of H, alkyl, alkenyl, aryl, heteroaryl, aralkyl, and alkaryl;
R³ is each independently selected from the group consisting of optionally substituted alkyl, optionally substituted alkenyl, optionally substituted aryl, and optionally substituted heteroaryl; or R¹ and R³ may be connected together to form a ring;
R² is selected from the group consisting of optionally substituted alkylene, optionally substituted alkenylene, optionally substituted arylene, optionally substituted heteroarylene;
D¹ and D² are each independently selected from the group consisting of hydrogen, optionally substituted alkoxy, optionally substituted aryloxy, optionally substituted acyloxy, optionally substituted alkyl, optionally substituted aryl, optionally substituted heteroaryl, optionally substituted amino, amido, cyclic amido, and cyclic imido, provided that D¹ and D² are not both hydrogen; and
Lⁱ is independently selected from the group consisting of optionally substituted alkylene, optionally substituted alkenylene, optionally substituted alkynylene, optionally substituted arylene, optionally substituted heteroarylene.

10. The tape according to claim 1, wherein the at least one luminescent dye is further represented by formula (III-a) or (III-b): 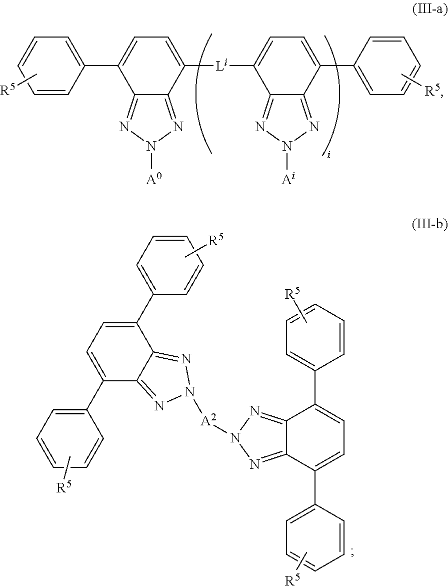
wherein:
i is an integer in the range of 0 to 100.
A⁰ and Aⁱ are each independently selected from the group consisting of optionally substituted alkyl, optionally substituted alkenyl, optionally substituted heteroalkyl, optionally substituted amido, optionally substituted alkoxy, optionally substituted cabonyl, and optionally substituted carboxy;
each R⁵ is independently selected from the group consisting of optionally substituted alkoxy, optionally substituted aryloxy, optionally substituted acyloxy, and amino;
A² is selected from the group consisting of optionally substituted alkylene, optionally substituted alkenylene, optionally substituted arylene, optionally substituted heteroarylene, ketone, ester, and 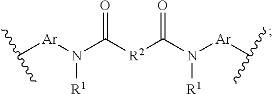
wherein Ar is optionally substituted aryl or optionally substituted heteroaryl; R¹ is selected from the group consisting of H, alkyl, alkenyl, aryl, heteroaryl, aralkyl, alkaryl; and R² is selected from the group consisting of optionally substituted alkylene, optionally substituted alkenylene, optionally substituted arylene, optionally substituted heteroarylene, ketone, and ester; or R¹ and R² may be connected together to form a ring; and
Lⁱ is independently selected from the group consisting of optionally substituted alkylene, optionally substituted alkenylene, optionally substituted alkynylene, optionally substituted arylene, optionally substituted heteroarylene.

11. The tape according to claim 1, wherein at least one luminescent dye is represented by formula (IV): 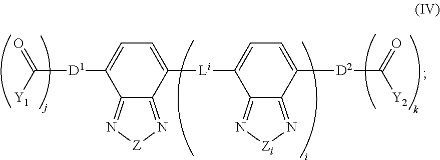
wherein,
i is an integer in the range of 0 to 100;
Z and Zᵢ are each independently selected from the group consisting of —O—, —S—, —Se—, —Te—, —NR⁶—, —CR⁶═CR⁶—, and —CR⁶═N—, wherein R⁶ is hydrogen, optionally substitute C₁-C₆ alkyl, or optionally substituted C₁-C₁₀ aryl; and
D¹ and D² are independently selected from the group consisting of optionally substituted alkoxy, optionally substituted aryloxy, optionally substituted acyloxy, optionally substituted alkyl, optionally substituted aryl, optionally substituted heteroaryl, optionally substituted amino, amido, cyclic amido, and cyclic imido;
j is 0, 1 or 2, and k is 0, 1, or 2;
Y₁ and Y₂ are independently selected from the group consisting of optionally substituted aryl, optionally substituted alkyl, optionally substituted cycloalkyl, optionally substituted alkoxy, and optionally substituted amino; and
Lⁱ is independently selected from the group consisting of optionally substituted alkylene, optionally substituted alkenylene, optionally substituted alkynylene, optionally substituted arylene, optionally substituted heteroarylene.

12. The tape according to claim 1, wherein the at least one luminescent dye is represented by formula (V-a) or formula (V-b): 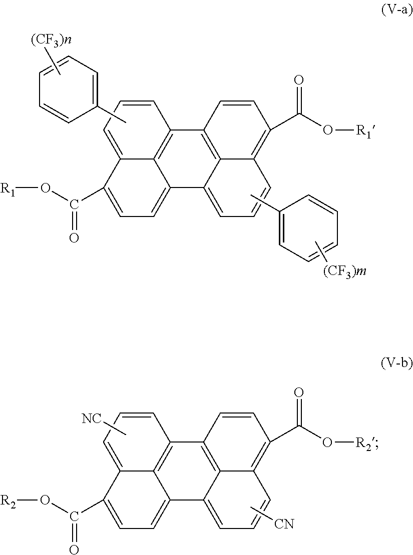
wherein R₁ and R₁′ in formula (V-a) are each independently selected from the group consisting of hydrogen, C₁-C₁₀ alkyl, C₃-C₁₀ cycloalkyl, C₁-C₁₀ alkoxy, C₆-C₁₈ aryl, and C₆-C₂₀ aralkyl; m and n in formula (V-a) are each independently in the range of from 1 to 5; and R₂ and R₂′ in formula (V-b) are each independently selected from the group consisting of a C₆-C₁₈ aryl and C₆-C₂₀ aralkyl.

13. The tape according to claim 1, wherein the polymer material is selected from the group consisting of polyethylenes, polypropylenes, polyester, polyamide, polycarbonate, polymethyl methacrylate, polyvinyl butyral, ethylene vinyl acetate, ethylene tetrafluoroethylene, polyimide, polystyrene, siloxane sol-gel, polyurethane, polyacrylate, and combinations thereof.

14. The tape according to claim 1, wherein the adhesive polymeric material in the pressure sensitive adhesive layer is selected from the group consisting of rubber, acrylic, silicone, vinyl alkyl ether, polyester, polyamide, urethane, fluorine, epoxy, ethylene vinyl acetate, or a mixture thereof.

15. The tape according to claim 1, wherein the adhesive polymeric material of the pressure sensitive adhesive layer is crosslinked using a crosslinking agent.

16. The tape according to claim 1, further comprising one or more of the following components:
at least one thickener selected from the group consisting of phenol resin, terpene-phenol-resin, terpene resin, xylene resin, rosin and hydrogenated resin;
at least one inorganic filler selected from the group consisting of calcium carbonate and carbon black;
a lubricant, an age resistor, a dye, a colorant, a pigment, a surfactant, a plasticizer, an antifoaming agent, a flame retardant, a light stabilizer, a thixotropy agent, an ultraviolet absorbent, a low-molecular weight polymer, an antioxidant, a heat-resistant stabilizer, a metal powder, a polymerization inhibitor, or any mixture thereof.

17. The tape according to claim 1, wherein the refractive index of the pressure sensitive adhesive layer is in the range of about 1.4 to about 1.7.

18. The tape according to claim 1, wherein the luminescent dye is present in the polymeric material of the pressure sensitive adhesive layer in an amount in the range of about 0.01 wt % to about 3.0 wt %.

19. The tape according to claim 1, wherein the thickness of the tape is between about 10 μm and about 2 mm.

20. The tape according to claim 1, wherein the thickness of the pressure sensitive adhesive layer is between about 1 μm to about 500 μm.

21. The tape according to claim 1, further comprising a removable liner attached to the pressure sensitive adhesive layer.

22. The tape according to claim 21, wherein the removable liner comprises a plastic film.

23. The tape according to claim 21, wherein the removable liner is selected from the group consisting of: fluoropolymers, polyethylene terephthalate, polyethylene, polypropylene, polyester, polybutene, polybutadiene, polymethylpentene, polyvinyl chloride, vinyl chloride copolymer, polybutalene terepthalate, polyurethane, ethylene-vinyl acetate, glassine paper, coated paper, laminated paper, cloth, nonwoven fabric sheets, and metal foil.

24. The tape according to claim 21, wherein the thickness of the removable liner is between about 10 μm and about 100 μm.

25. The tape according to claim 1, wherein additional materials or layers are used in the tape such as polymer films, or adhesive layers to adhere additional layers to the system.

26. The tape according to claim 1, further comprising an additional polymer layer containing a UV absorber.

27. The tape according to claim 26, wherein the additional polymer layer comprises a second luminescent dye.

28. A method of improving the performance of a solar harvesting device comprising applying the tape of claim 1 to the device.

29. The method of claim 28, wherein the tape is applied to the solar harvesting device using a roll laminator.

30. The method according to claim 28, wherein the solar harvesting device is selected from the group consisting of a Silicon based device, a III-V or II-VI PN junction device, a Copper-Indium-Gallium-Selenium (CIGS) thin film device, an organic sensitizer device, an organic thin film device, or a Cadmium Sulfide/Cadmium Telluride (CdS/CdTe) thin film device

31. The method according to claim 28, wherein the solar harvesting device comprises a light incident surface comprising a glass or a polymer.
